(19) United States
(12) Patent Application Publication
(10) Pub. No.: US 2016/0041089 A1
(43) Pub. Date: Feb. 11, 2016

(54) SYSTEMS AND METHODS UTILIZING LONG WAVELENGTH ELECTROMAGNETIC RADIATION FOR FEATURE DEFINITION

(71) Applicants: Minna Hovinen, Edina, MN (US); Mathias Schubert, Lincoln, NE (US); Gerald Finken, Woodbury, MN (US); Greg Schmitz, Princeton, MN (US); Tino Hofmann, Lincoln, NE (US); Stefan Schöche, Lincoln, NE (US)

(72) Inventors: Minna Hovinen, Edina, MN (US); Mathias Schubert, Lincoln, NE (US); Gerald Finken, Woodbury, MN (US); Greg Schmitz, Princeton, MN (US); Tino Hofmann, Lincoln, NE (US); Stefan Schöche, Lincoln, NE (US)

(21) Appl. No.: 14/454,979

(22) Filed: Aug. 8, 2014

(51) Int. Cl. G01N 21/25; H01J 37/305

(52) U.S. Cl. CPC G01N 21/255; H01J 37/3053; G01N 2021/1757

(57) ABSTRACT

Methods that include directing an incident beam towards a substrate, the substrate having one or more features formed thereon wherein the incident beam has a wavelength from about 10 μm to about 10 mm, and the incident beam interacts with the substrate to form a modulated beam; varying one or more characteristics of the incident beam while directed towards the substrate; detecting the modulated beam while varying the one or more characteristics of the incident beam to collect a spectrum; and determining at least one spatial metric of the at least one feature based on the collected spectrum.

### SUMMARY

Disclosed are methods that include directing an incident beam towards a substrate, the substrate having one or more features formed thereon wherein the incident beam has a wavelength from about 10 μm to about 10 mm, and the incident beam interacts with the substrate to form a modulated beam; varying one or more characteristics of the incident beam while directed towards the substrate; detecting the modulated beam while varying the one or more characteristics of the incident beam to collect a spectrum; and determining at least one spatial metric of the at least one feature based on the collected spectrum.

Also disclosed are systems that include a source of radiation, the radiation having a wavelength from about 10 μm to about 10 mm; a detector configured to detect radiation having a wavelength from about 10 μm to about 10 mm; a sample support configured to hold at least one wafer; and a wafer processing system configured to carry out at least one process on the at least one wafer on the platform.

Also disclosed are systems that include a source of radiation, the radiation having a wavelength from about 10 μm to about 10 mm; a detector configured to detect radiation having a wavelength from about 10 μm to about 10 mm; a sample support configured to hold at least one wafer; and a process environment configured to carry out one or more processes on the at least one wafer, wherein the sample support is positioned within a process environment, and the source of radiation and the detector are positioned external to but in communication with the process environment.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### BRIEF DESCRIPTION OF THE FIGURES

FIG. 1 schematically illustrates a disclosed system.

FIG. 2 depicts an illustrative disclosed method.

FIG. 3 schematically depicts embodiments of a disclosed system including a processing system.

FIG. 4 is a perspective view of an illustrative magnetic writer.

FIGS. 5A and 5B show an illustrative photocube, with FIG. 5A showing a computer aided design (CAD) image of one photocube and FIG. 5B showing a photograph of a related wafer.

FIGS. 6A and 6B show the geometry of an illustrative instrument and sample holder and the two measurement positions utilized for the example below.

FIG. 7 shows data for a single frequency (850 GHz) in dependence of the angle of incidence for the three processed wafers on both measurements positions (i.e., 2 different sample orientations). Plotted are the Mueller-Matrix elements MM12/MM21 (related to the ellipsometric angle Ψ), MM33 (related to the ellipsometric angle Δ), and the accessible off-diagonal Mueller-Matrix elements MM13, MM23, MM31, and MM32 (indicative for anisotropy in the samples).

FIGS. 8A, 8B, and 8C show data for a single frequency (850 GHz) in dependence of the angle of incidence for two measurement positions for each wafer. Plotted are the Mueller-Matrix elements MM12/MM21 (related to the ellipsometric angle Ψ), MM33 (related to the ellipsometric angle Δ), and the accessible off-diagonal Mueller-Matrix elements MM13, MM23, MM31, and MM32 (indicative for anisotropy in the samples).

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Photo lithography process involve precise placement of the imaged features in relation to the underlying features imaged at prior photo lithography steps (vertical placement), and in relation to the adjacent features imaged at previous cycles (lateral placement). The metrics in question can be referred to as overlay for the vertical placement and co-linearity or image positioning for the lateral placement.

Currently utilized feature placement metrology suffers from drawbacks. Overlay optical metrology depends on fabrication of special measurement targets, scanning electron microscopy (SEM) is localized and destructive, and the optical registration tools are slow and expensive. Within the feature definition there are subsequent process steps that pose further challenges for metrology, such as bevel angle static ion milling. In addition to the above mentioned difficulties the post-mill metrology can be even more challenging as metrology targets get milled asymmetrically. In milling processes where the bevel length is >300 nm, optical scatterometry cannot be used and optical inspection does not have resolution at <100 nm.

Disclosed herein are methods and systems for determining one or more characteristics of a substrate. Disclosed methods and systems can be characterized as not requiring special metrology features, relatively fast, non-destructive, and relatively inexpensive.

Ellipsometry terahertz (THz) and surrounding radiation (e.g., far infrared radiation) is a relatively new technology that has begun to be developed since sources providing such radiation have become commercially available. Terahertz waves are part of the electromagnetic spectrum between infrared waves and microwaves. As such, terahertz waves can be said to have wavelength in the range from 300 μm to 3 mm. Terahertz radiation is not sensitive to most environmental factors and as such ellipsometry measurements made using terahertz waves can be performed at room temperatures and pressures.

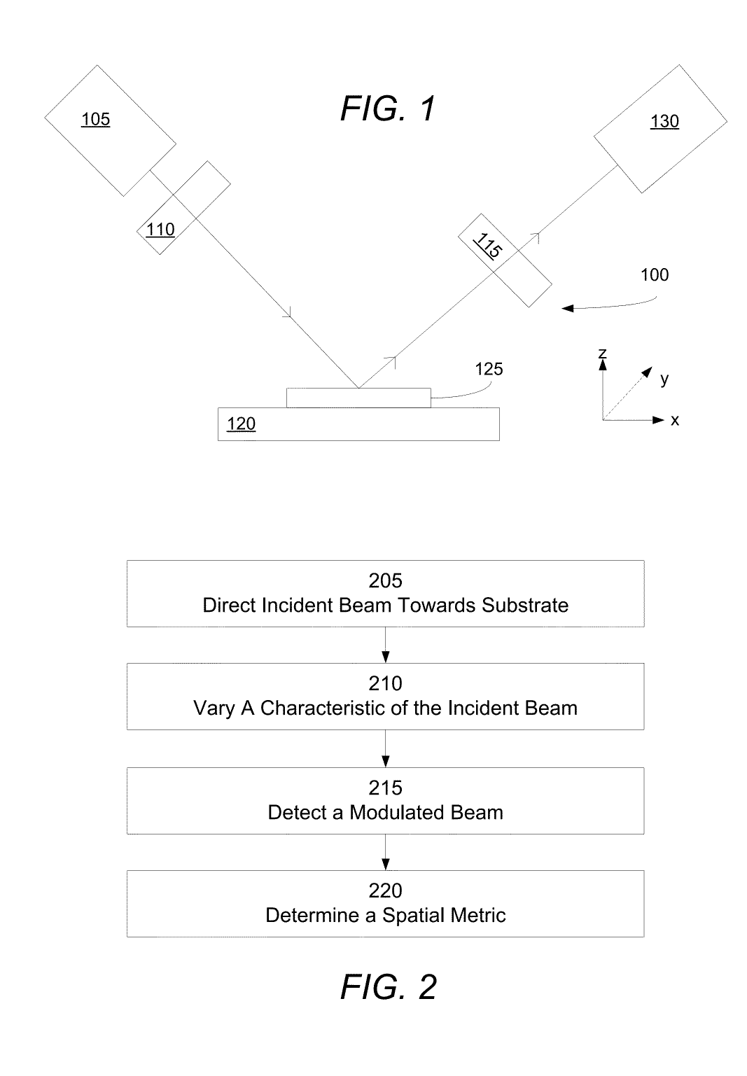

FIG. 1 schematically illustrates embodiments of disclosed systems. FIG. 1 shows a system 100 that includes a source of radiation, source 105, a support 120, and a detector 130. The system 100 can also include a polarizer 110, and an analyzer 115. The system 100 can generally be configured so that radiation exits the source 105, can be modulated by a polarizer 110, impinges upon a sample 125 supported by the support 120, is modulated by the analyzer 115, and is ultimately detected by the detector 130. In some embodiments, disclosed systems can utilize one or more components such as those disclosed in U.S. Pat. Nos. 8,169,611; 8,416,408; 8,488,119 and 8,705,032, the disclosures of which are incorporated in their entirety herein by reference thereto.

Illustrative systems 100 can include a source of radiation 105. Radiation that can be utilized in disclosed systems can be described by the frequency thereof. For example radiation that can be utilized in disclosed systems can have a frequency of at least 30 gigahertz (GHz), and in some embodiments not greater than 30 terahertz (THz). Radiation that can be utilized in disclosed systems can also be described by the wavelength thereof. For example radiation that can be utilized in disclosed systems can have a wavelength of at least 10 μm, in some embodiments at least 100 μm, and in some embodiments at least 300 μm. Radiation that can be utilized in disclosed systems can have a wavelength of not greater than 10 mm, in some embodiments not greater than 1 mm, or in some embodiments not greater than 3 mm. Radiation that can be utilized in disclosed systems can be referred to as far-infrared radiation, terahertz (THz) radiation, near microwave radiation, or combinations thereof. In some embodiments terahertz radiation can be utilized in disclosed systems.

Disclosed systems 100 can include a number of different types of devices as sources of radiation 105. Illustrative types of sources of radiation 105 can include, for example; Smith-Purcell cells, free electron lasers, and backward wave oscillators (BWO). Smith-Purcell cells are devices which direct an energetic beam of electrons very close to a ruled surface of a diffraction grating. The effect on the trajectory of the beam is negligible, but a result is that Cherenkov radiation in the terahertz frequency range can be created. Free electron lasers will accelerate a beam of electrons relativistic speeds causing them to pass through a periodic transverse magnetic field. The array of magnets is sometimes referred to as an undulator or “wiggler” as it causes the electrons to form a sinusoidal path. The acceleration of electrons causes a release of photons, which is “synchrotron radiation”. The electron motion is in phase with the field of the released electromagnetic radiation and therefore the fields add coherently. Instabilities in the electron beam resulting from interactions of the oscillations in the undulators lead to emission of electromagnetic radiation. The wavelength of the emitted electromagnetic radiation can be adjusted by adjusting the energy of the electron beam and/or magnetic field strength of the undulators, to be in the terahertz range. Backward wave oscillators are vacuum tube systems that include an electron gun that generates an electron beam and causes it to interact with an electromagnetic wave traveling in a direction opposite to that of ejected electrons such that terahertz frequency oscillations are sustained by interaction between the propagating traveling wave backwards against the electron beam.

Illustrative systems 100 can also include a detector 130. Detectors that can be utilized as detector 130 are those that can detect radiation from source 105, radiation that may have been modulated by the sample 125, and combinations thereof. Illustrative types of devices that may be utilized as detector 130 can include, for example Golay cells, and Bolometers. A Golay cell operates by converting a temperature change resulting from electromagnetic radiation impinging onto material into a measurable signal. Generally when electromagnetic radiation is caused to impinge on blackened materially it heats a gas (E. G., Xenon) in a first chamber of an enclosure. That heating causes a distortable reflecting diaphragm/film adjacent to said first chamber to change shape. In a second chamber, separated from the first by the diaphragm/film an electromagnetic beam is caused to reflect from the film and into a photocell, which in turn converts the received electromagnetic radiation into an electrical signal. A Bolometer operates by using the effect of a changing electrical resistance caused by electromagnetic radiation impinging onto a blackened metal.

Illustrative systems 100 can also include a source of radiation 105 and a detector 130 that are solid-state sources and detectors of terahertz frequency electromagnetic radiation. Nagashima et al. (“Measurement of a Complex Optical Constants of a Highly Doped Si Wafer Using Terahertz Ellipsometry”, Nagashima et al., Applied Phys. Lett. vol. 79, No. 24, (Dec. 10, 2001)) disclosed that terahertz pulses can be generated by a bow-tie photoconductive radiation antenna excited by a mode-locked Ti-sapphire laser with 80 femtosecond (Fs) time width pulses. A detection antenna can be formed from a dipole-type photoconductive antenna with a 5 μm gap fabricated on thin film LT-GaAs. A commercially available version of a solid-state source and detector that spans the range from 8 GHz to 1000 GHz can be obtained from AB Millimeter (Paris, France).

Illustrative systems 100 can also include a sample support 120. The sample support 120 can be configured in virtually any way as long as a sample 125 can be positioned thereon, or in some part therein. A sample support 120 can optionally be configured to move the sample 125 with respect to one or more other components of the system 100 which it is located in. For example, a sample support 120 can be configured to move the sample up or down (in the z dimension), side to side (in the x, y, or both dimensions), at an angle (in both the z dimension and one other dimension at the same time), rotationally, or any combination thereof. In some embodiments, a sample support can be particularly configured to support a wafer. In some embodiments, sample supports that could be utilized for lithography or more specifically microlithography samples (e.g., wafers) could be utilized as sample support 120. In some embodiments, sample supports utilized herein can include components for aligning the wafer, other components with respect to the wafer, or both.

Illustrative systems 100 can be utilized with virtually any type of sample 125. A sample can be anything having one or more materials, features, or some combination thereof deposited or formed thereon or at least partially therein. A sample can also be referred to as a substrate, or a wafer. A feature can also be referred to as a structure. A feature can generally be described as a three-dimensional entity on a sample or in a sample or part of a sample. Samples may include multiple layers of materials; an individual feature can be composed of one or more than one layer of material. In some embodiments a sample 125 can include various types of features or structures thereon or at least partially therein. In some embodiments a sample 125 can include one, or more than one feature formed thereon.

A feature or multiple features can be described by one or more than one spatial metric. Illustrative spatial metrics can include, for example a dimension of a feature (height, width, length, etc.), a relative dimension (e.g., a dimension of one feature with respect to another feature), an angle of the feature or some portion of the feature with respect to an axis (e.g., a wall angle), a shape of a feature (e.g., a corner radius), and a relative location of one feature with respect to another feature (e.g., distance). In some illustrative embodiments, a sample can include features that have been formed via semiconductor processing methods. Particularly illustrative embodiments can include, for example; or wafers with one or more than one magnetic memory device (e.g., magnetic memory or devices to read and/or write magnetic memory). The at least one feature or the at least one spatial metric of the at least one feature can be a result of, controlled by, or any combination thereof one or more processes. Illustrative processes can include, for example, a lithography process, a deposition process, a milling process, an etching process, a polishing process, or some combination thereof.

Illustrative systems 100 can optionally include at least one polarizer 110 and at least one analyzer 115. The polarizer 110 (and therefore the analyzer 115) is an optional component of disclosed systems. In systems where a polarizer (and therefore an analyzer) is not included, the system could be described as function as a reflectometer or a spectrometer, instead of an ellipsometer. A polarizer 110 and an analyzer 115 can also be referred to as polarization state altering components. Illustrative polarizers and analyzers that can be utilized herein can be linear polarizers or polarizers that provide partially linearly polarized radiation. Exemplary types of polarizers can include, for example non-Brewster angle components, and dual tipped wire grid polarizer systems. Polarizers and analyzers useful in disclosed systems can also be rotated, for example. In some illustrative systems more than one polarizer, more than one analyzer, more than one type of polarizer or analyzer, or any combination thereof can be utilized.

Although not depicted in FIG. 1, disclosed systems 100 can also include other optional components, including for example compensators, other optical components, or combinations thereof. Disclosed systems 100 can also include elements and/or devices to enhance the signal to noise ratio of the detected radiation. One of skill in the art, having read this specification, would know how such optional components could be utilized in disclosed systems.

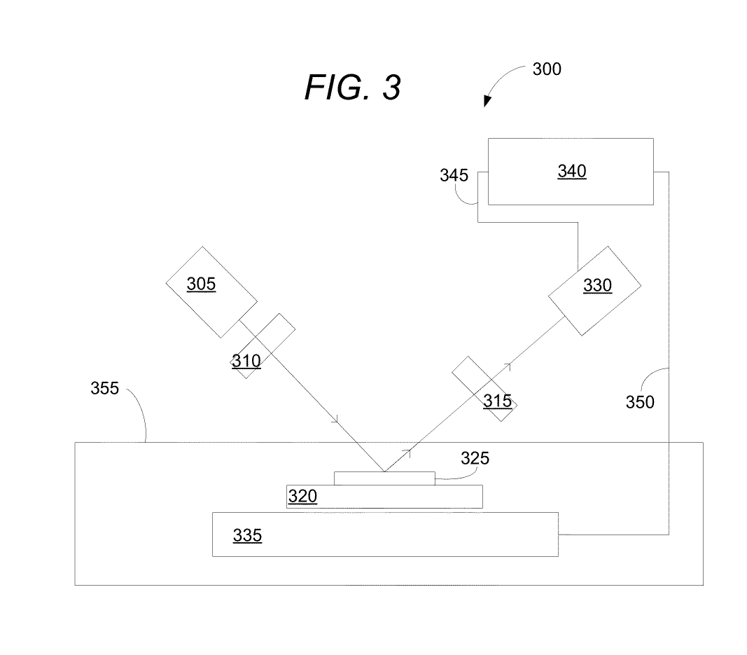

Also disclosed herein are methods. FIG. 2 depicts an illustrative method. A first step in illustrative methods can include step 205, directing an incident beam towards a substrate. The incident beam can come from sources such as those discussed above. The sources can be combined with other components such as polarizers, compensators, optics, or any combination thereof. The incident beam can be directed towards the substrate at any angle. In some embodiments an incident beam can be directed towards a substrate at a relatively large angle of incidence. Relatively large angles of incidence can also be referred to as gazing incidence. The angle of incidence can be controlled by position of the detector, the position of the sample, or any combination thereof.

Beams that are useful in disclosed systems and methods can also be described as collimated beams. Optional optical elements can be utilized in systems or methods to form collimated beams. Beams can also be described by the size of the beam when it hits the sample. In some embodiments a beam can have a size on a millimeter scale. In some embodiments a beam can have a diameter of at least 1 mm, or in some embodiments at least 2 mm. In some embodiments a beam can have a diameter of not greater than 20 mm, or in some embodiments not greater than 15 mm.

Another step in illustrative methods can include step 210, varying a characteristic of the incident beam. Varying a characteristic of the incident beam can also be referred to as scanning. In some embodiments the angle of incidence, the wavelength of the incident beam, the polarization, the duty cycle, or any combination thereof can be varied. In some embodiments the angle of incidence of the incident beam, which can be defined as the angle of the incident beam to the surface normal within the plane of incidence, can be varied. In illustrative embodiments, the angle of incidence of an incident beam can be zero degrees. Such an embodiment could be accomplished, for example, via use of a beam splitter. In some illustrative embodiments, the angle of incidence can be not less than 10 degrees, or in some embodiments not less than 45 degrees. In illustrative embodiments the angle of incidence of an incident beam can be not greater than 90 degrees, or in some embodiments not greater than 45 degrees.

It should be noted that step 205 and step 210 can be carried out at substantially the same time. Alternatively a characteristic of the incident beam can be varied and then the beam can be directed towards the substrate, or the beam can be directed towards the substrate and then a characteristic of the incident beam can be varied.

When an incident beam interacts with the sample a modulated beam is formed. A modulated beam can include a reflection of the incident beam off of the sample, a scattering of the incident beam off of the sample, a diffraction of the incident beam off of the sample, or any combination thereof. A modulated beam includes at least one characteristic that is different than the incident beam that strikes the sample. The at least one different characteristic can be utilized to determine at least one spatial metric of at least one feature of the sample.

A next step in illustrative methods can be step 215, detecting a modulated beam. The modulated beam can be detected using detector such as those discussed above. The detectors can be combined with other components such as polarizers, compensators, analyzers, optics, or any combination thereof. The step of detecting a modulated beam can also be carried out using a processor or system including one or more processors. The type of detector utilized to detect the modulated beam can depend at least in part on the source that provided the incident beam. Detection of the modulated beam, which was the result of an incident beam having one or more characteristics thereof varied, can also be referred to as collecting a spectrum. A spectrum collected as a result of an incident beam interacting with a sample can be referred to as a collected spectrum.

A next step in illustrative methods can be step 220, determining a spatial metric. Determining one or more spatial metrics of one or more features on the sample can be accomplished by a processor or a system including one or more processors (and other components such as memory, etc.) analyzing the collected spectrum. There are numerous ways in which a collected spectrum can be analyzed, including for example comparing or more specifically normalizing the collected spectrum with an acceptable spectrum, comparing the collected spectrum with a modeled theoretical spectrum, taking the differential of the collected spectrum and a previously collected spectrum from the same sample at an earlier stage, or some combination thereof.

The step of determining one or more spatial metric can include analysis methods and constructs typically utilized in ellipsometry. One such construct can be referred to as a Mueller matrix. Details about the Mueller matrix and its use thereof can be found in numerous publications, including for example, M. Schubert, Polarization-dependent optical parameters of arbitrarily anisotropic homogeneous layered systems, Phys. Rev. B 53, 4265, 15 Feb. 1996. A general representation of the transformation of the state of polarization of light upon reflection or scattering by an object or sample is described by S′=MS, where S and S′ are the Stokes vectors of the incident and scattered radiation, respectively, and M is the real 4×4 Mueller matrix that succinctly characterize the linear (or elastic) light-sample interaction. The 4×4 Mueller matrix provides 16 elements for M that are nonzero and independent. Any one or more than one of these elements can be utilized to determine a spatial metric. One of skill in the art, having read the specification, will understand how to utilize a Mueller matrix to determine one or more than one spatial metric.

In some embodiments the Mueller matrix elements M₂₁, which is related to the ellipsometric angle Ψ may be utilized to determine a spatial metric. In some embodiments, the Mueller matrix elements M₂₁ may be particularly useful to determine, for example a milling offset on the order of a few tens of nanometers. Particular examples that utilize one or more of the Mueller matrix elements are discussed in more detail below.

In some embodiments, illustrative methods can also include a step of obtaining an acceptable spectrum. The step of obtaining an acceptable spectrum may include directing an incident beam towards an acceptable substrate, varying a characteristic of the incident beam, and detecting a modulated beam from the acceptable substrate to collect an acceptable spectrum. An acceptable substrate can be one where the one or more than one feature has an acceptable or desired spatial metric. Some methods can impair a collected spectrum to the acceptable spectrum in order to determine a spatial metric. In such embodiments determining the spatial metric can include normalizing with the collected spectrum to the acceptable spectrum to determine how they differ. In some embodiments, a method can also include determining or setting an acceptable difference between the collected spectrum and the acceptable spectrum. In a case where a collected spectrum has a difference that is within the acceptable diff level, the sample can be deemed acceptable.

In some embodiments illustrative methods can also include a step of obtaining a modeled theoretical spectrum. The step of obtaining a modeled theoretical spectrum can include utilizing one or more pieces of software to predict a spectrum that would be generated by a sample having a particular feature or features. A modeled theoretical spectrum can be predicted from the technical specifications of a substrate that is to be formed using a particular processing flow, for example.

In some embodiments, illustrative methods can also include a step of affecting a process based on the determined spatial metric. As discussed above, the at least one feature or the at least one spatial metric of the at least one feature can be a result of, be controlled by, or any combination thereof one or more processes. Illustrative processes can include, for example, lithography processes, deposition processes, milling processes, etching processes, polishing processes, or some combination thereof. Once a spatial metric has been determined, one or more processes (such as any one or more of those exemplified herein or others) can be changed based on the determined spatial metric. The act of changing the one or more processes can be carried out off-line, on-line (also referred to as in situ), or a combination thereof. In some embodiments where the one or more processes to be changed is happening or will be changed on-line, further method steps or components can be utilized to effect the change, including for example controllers, feedback loops, etc.

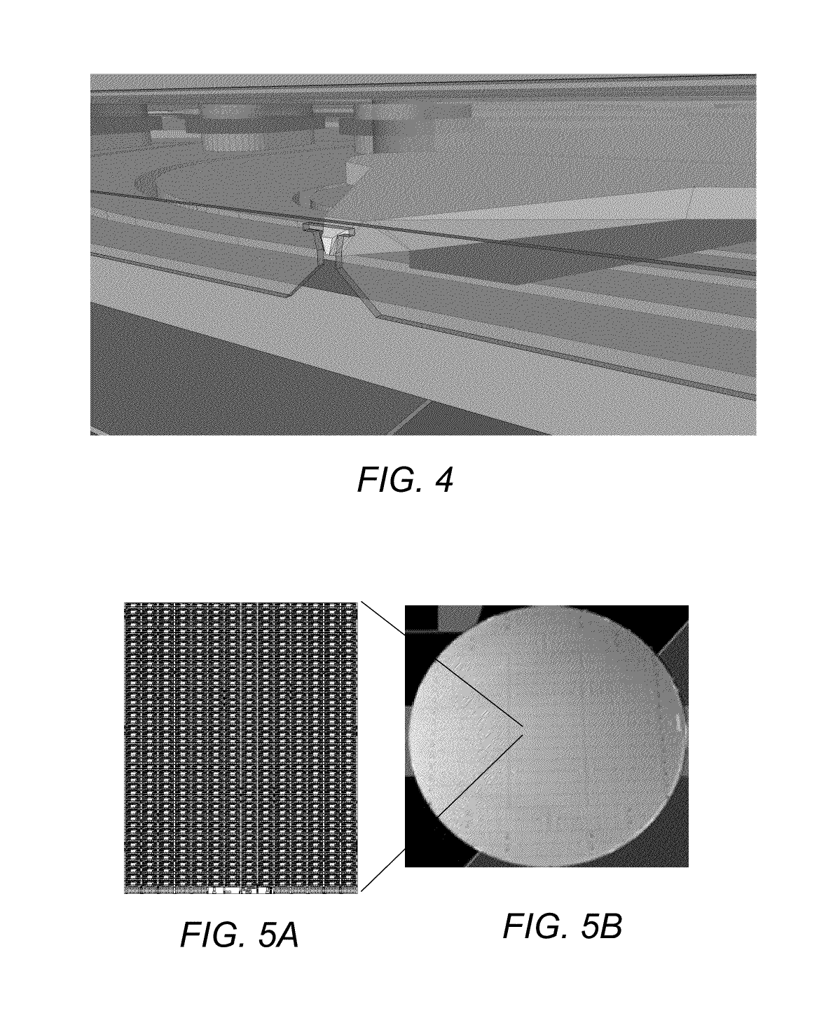

FIG. 3 discloses another illustrative system. The system 300 depicted in FIG. 3 can include components similar to the system 100 illustrated in FIG. 1. For example, the system 300 can include a source 305, a sample support 320, and a detector 330. System 300 can also include a polarizer 310, and analyzer 315. The sample support 320 can be configured to hold a sample 325. The source 305, the sample support 320, the detector 330, the optional polarizer 310, and the optional analyzer 315 can all be located within or in communication with the process environment 355. The process environment 355 can include numerous components and systems configured to carry out a particular process or processes. Illustrative processes can include, for example, lithography processes, deposition processes, milling processes, etching processes, polishing processes, or some combination thereof. The source 305, the sample support 320, the detector 330, the optional polarizer 310, and the optional analyzer 315 can be described as configured to be in contact or communication with the in-situ process environment 355. In some embodiments, the source 305 can be configured so that an incident beam from the source 305 interacts with the sample 325 that is located in the in-situ process environment 355 and the modulated beam from the sample 325 leaves the in-situ process environment 355 and is detected by the detector 330. This can be accomplished, for example by configuring the process environment or the process environment enclosure with windows that allow the incident beam and the modulated beam to pass.

The system 300 can also include a processor 340. The processor 340 can be configured to obtain information from the detector 330 via detector-processor connection 345. The processor 340 can function, at least in part to determine the one or more spatial metric based on information from the detector 330. The processor 340 can also optionally be configured in communication with a controller 335 via a processor-controller connection 350. The controller 335 can function, at least in part to control the process or processes being carried out in the process environment 355. This configuration of components can be characterized as providing real-time control, or a feedback loop based on the modulated beam and/or the spatial metric determined from the sample.

The above described spatial metric methods can be used in an alignment system. In some embodiments, an aligning relationship of two articles can be determined by features, for example by alignment marks. The use of a laser source renders such a system especially useful because laser beams remain coherent over long distances. Illustrative devices that could benefit from such alignment systems may therefore include systems where two articles to be aligned are separated by a significant (e.g., tens of feet) distance. Illustrative devices that could benefit from such alignment systems may also include systems where two articles to be aligned are separated by one or more visual obstacles that are transparent to radiation having a wavelength between 10 μm and 10 mm. Illustrative devices that could benefit from such alignment systems may also include systems where two articles to be aligned are separated by environmentally formed interferences, including, for example smoke, haze, fog, smog, etc. Illustrative types of devices that could benefit from such an alignment system can include, for example telescopes, and lithographic processing systems.

### EXAMPLES

Use of Disclosed System and Method for Monitoring Angled Static Ion Milling

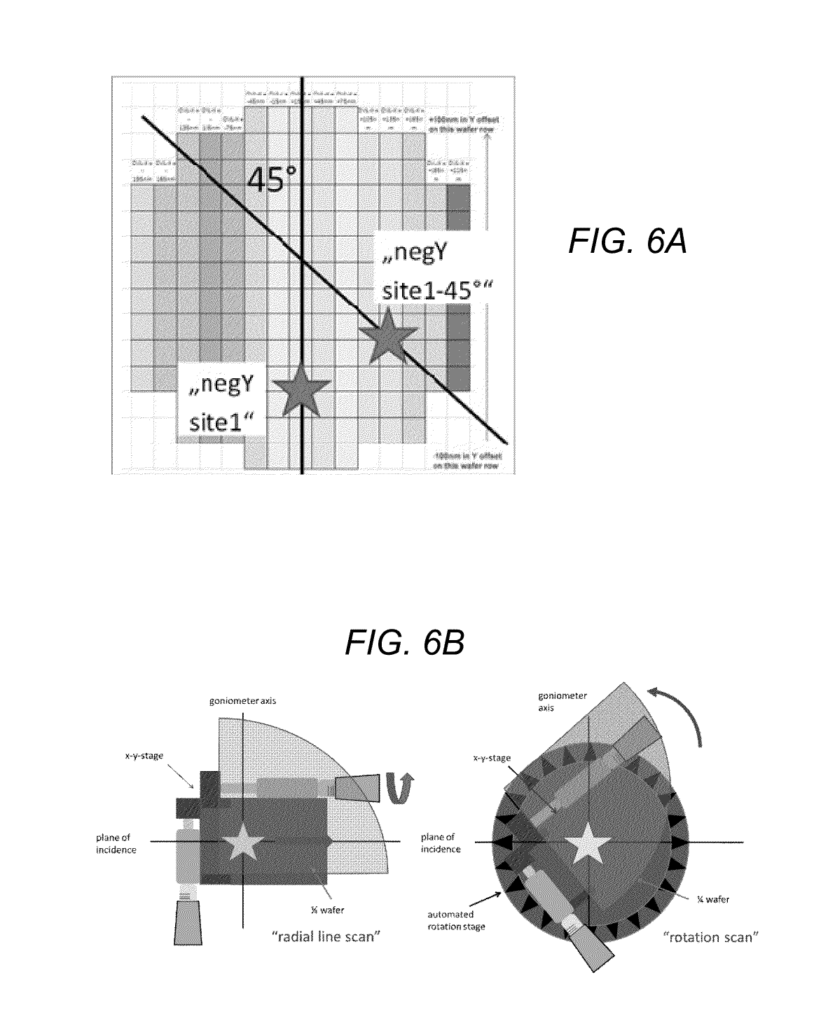

A magnetic recording head has two main components: a writer and a reader. The purpose of the writer is to deliver a well-controlled magnetic flux to the media to manipulate the magnetic bits in the process of writing digital data. The ever increasing areal densities have pushed the magnetic track width down to the nanoscale. One method of being able to deliver a strong magnetic field in these dimensions is to give the writer a complex shape, which is depicted in FIG. 4.

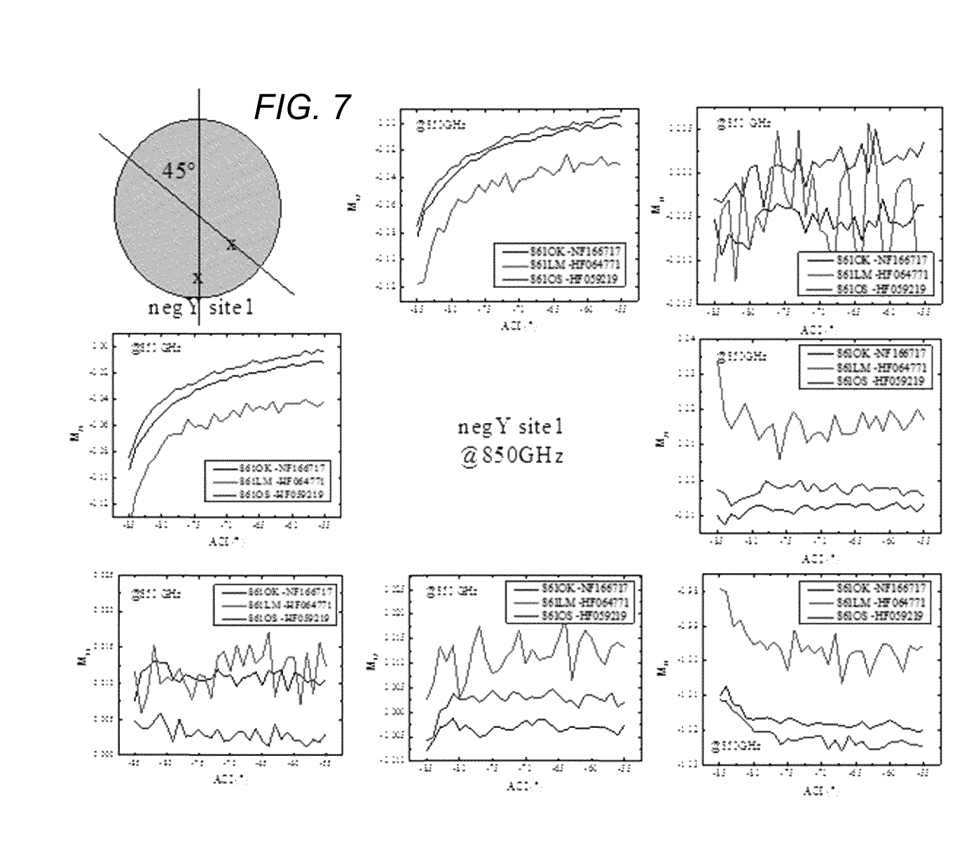

One of the many process steps leading to this geometry is the so called bevel mill where a highly critical angle is formed by ion milling. The ion beam is directed in an angle and the wafer is not rotated during milling which is also known as static mill. The pattern to be milled is defined in a prior photolithography step. The areas to be milled are left open while the other parts are covered with a mask. The within wafer non-uniformity of the milling process is too large and would result in high quality devices only at a limited portion of the wafer without further control. The photo-process is designed to compensate for the milling non-uniformity by using so-called scaling factors at the different portions of the wafer. This is done by applying pre-determined offsets for the photomask as the stepper tool is exposing the wafer cube by cube. The photocube is shown in FIGS. 5A and 5B, with FIG. 5A showing a computer aided design (CAD) image of one photocube having a dimension of about 8×13 mm² and FIG. 5B showing a photograph of a wafer with a diameter of 200 mm.

Optical overlay measurements provide good metrology for the photo mask offsets so that the success of scaling can be monitored right after the photo-process. However, it is also essential to verify that the milling process has not changed and is still providing the corresponding milling pattern across the wafer. There is currently no metrology either in-situ in the milling chamber or an ex-situ post-mill measurement. The optical overlay measurement tends to fail as the metrology targets get milled in a skewed fashion as well. Cross-sectioning SEM or TEM is not practical to cover the whole wafer. Optical scatterometry or ellipsometry are not feasible because the final bevel length is too large at 400 nm.

This example utilizes disclosed systems and methods to carry out ellipsometry on this system. The size of the photo features and the fact that the whole photocube is shifted in unison indicates that a wavelength in the terahertz (THz), for example 300 μm-1 mm could be useful.

Five wafers with various processing were evaluated:

861LM on target “good water 1” with Y-scaling correction, no X-overlay offset;

861OS on target “good wafer 2” with Y-scaling correction, no X-overlay offset;

861OK “bad wafer” with Y-scaling milling offset+−100 nm, X-overlay offset−195+225 nm;

861MC interrupted good wafer reference. Top aC and pink patterning missing; and

AlTiC substrate reference.

Wafers were processed to create only the writer part of the full build recording head device. Even the writer part was not completed but was stopped after the bevel angled static mill in order to test metrology for the mill. The milling direction was from positive Y to negative Y. The main focus was on photo placement and how it would affect the final milling result. If the photomask had an offset to the underlying pattern, an overlay offset, then different parts of the filmstack would get milled resulting possibly in a large change in the THz response.

Mueller-Matrix ellipsometry in the THz spectral range (650 GHz to 1020 GHz) was applied in order to investigate changes in the anisotropy and optical response on test wafer structures depending on successful and misaligned lithography processing steps. Test measurements in reflection were performed on a bare AlTiC substrate and three completely processed wafers, of which two were deemed “good” and one “bad” (wafer IDs-substrate IDs: 861LM-HF064771, 861OS-HF059219, 861OK-NF166717). The 3×3 subset of the Mueller matrix without fourth column and row (due to the absence of compensators in the setup) is measured and discussed here. The spectroscopic data acquisition was reduced to single wavelength and multiple angle of incidence scans were favored over spectroscopic scans due to the highly reflective nature of the samples in the THz spectral range. Variations of the data were detected as a function of the angle of incidence. These variations differed between different wafers and different wafer positions/different wafer position rotations.

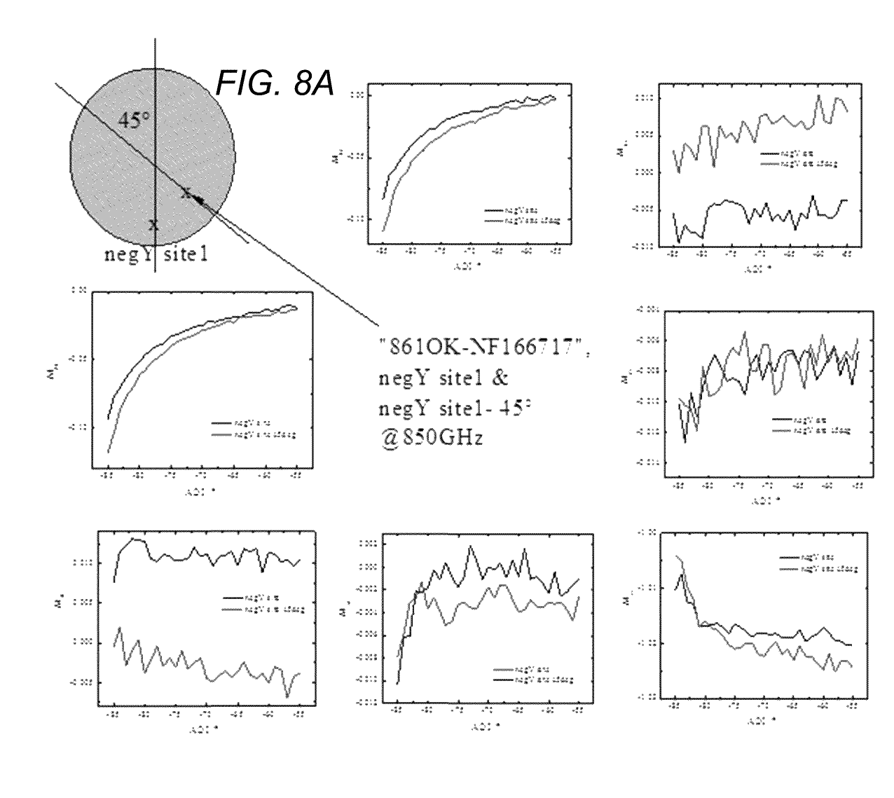

Two different measurement positions were chosen according to the geometry of the existing instrument and sample holder (stars in FIG. 6A). For both positions, the wafer was placed so that the symmetry axis (black lines) was oriented along the center of the sample holder. For the measurement position “negY site 1-45°” the wafer was rotated by hand around the center by 45° but not moved laterally, resulting in a laterally shifted measurement position. The size of the wafers and the current sample holder design did not allow shifting the wafer back to the original measurement spot. An appropriate sample stage will require capabilities of x-y-translation and automated sample rotation and should be fabricated prior to further measurements. This would allow investigation of the variation in the Mueller matrix elements in dependence of the azimuthal sample orientation on a fixed lateral position on the wafer (rotation scan) and/or the change of the lateral position on the wafer (radial line scan).

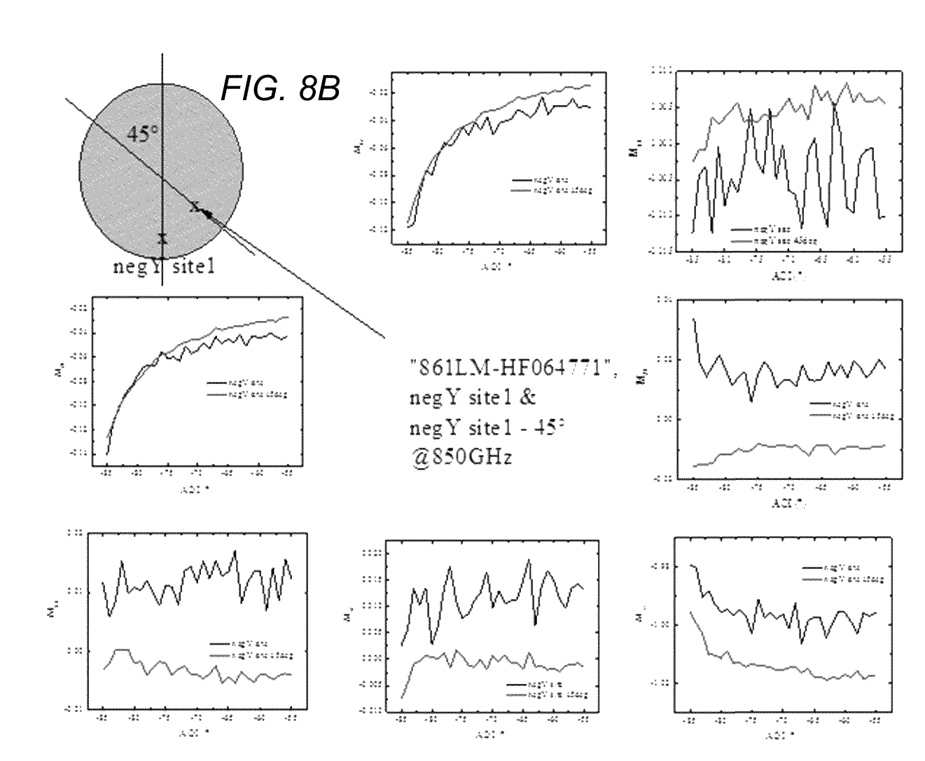

The figures presented in FIG. 7 show data for a single frequency (850 GHz) in dependence of the angle of incidence for the three processed wafers on both measurements positions (i.e., 2 different sample orientations). Plotted are the Mueller-Matrix elements MM12/MM21 (related to the ellipsometric angle Ψ), MM33 (related to the ellipsometric angle Δ), and the accessible off-diagonal Mueller-Matrix elements MM13, MM23, MM31, and MM32 (indicative for anisotropy in the samples). All measurements were performed without changes to the instrument between the measurements (same calibration). Modeling the data was not attempted so far.

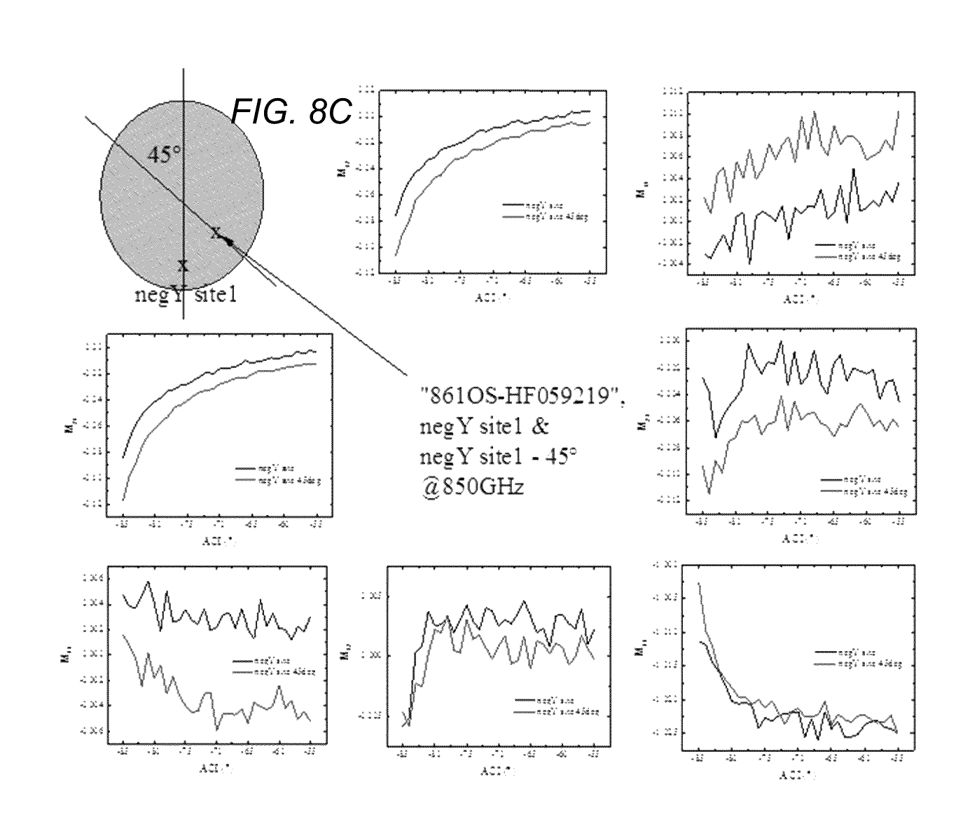

Similar shifts in MM12/MM21 as for the measurement position “negY site1” are also found for the position “negY site—45°”, which is laterally shifted and for which the wafer is rotated by 45° compared to the first spot. In order to evaluate relative changes in the Mueller-Matrix elements on the individual wafers, a comparison of the two measurement positions for each wafer is shown in FIGS. 8A, 8B, and 8C respectively.

The comparison of the two measurement positions on the three wafers shows a larger splitting of the off-diagonal block Mueller-Matrix elements upon rotation for the wafer “861LM-HF064771” compared to the other two. This finding is in agreement with the different optical properties of this wafer found in the on-diagonal block elements MM12/MM21 for this wafer compared to the other wafers and might indicate an increased optical anisotropy for this particular wafer. Evaluation of this statement, also in comparison to the other two wafers, would require detailed measurements for different azimuthal sample orientations in steps of a few degrees. A suitable automated sample rotation stage with capabilities of a- and y-translation could be beneficial for that purpose and is currently not available, but a proposed version of such a system is depicted in FIG. 6B.

As seen from this example, a simple line scan across the wafer could verify the success of static mill.

For most steps in semiconductor or TFH (thin film head) processing the overlay and image-positioning measurement target size is 100 nm-10 μm and the accuracy requirement is <1 nm, suitable for electronmicroscopic and optical methods. However, there are processes with dimensions in the hundred micrometer range with registries spanning millimeters and accuracy requirements<100 nm that are at the capability limit of the current metrology tools. There is a metrology gap at the large target (>10 μm) long range (>1 mm) feature definition.

One skilled in the art will appreciate that the articles, devices and methods described herein can be practiced with embodiments other than those disclosed. The disclosed embodiments are presented for purposes of illustration and not limitation. One will also understand that components of the articles, devices and methods depicted and described with regard to the figures and embodiments herein may be interchangeable.

All scientific and technical terms used herein have meanings commonly used in the art unless otherwise specified. The definitions provided herein are to facilitate understanding of certain terms used frequently herein and are not meant to limit the scope of the present disclosure.

As used in this specification and the appended claims, “top” and “bottom” (or other terms like “upper” and “lower”) are utilized strictly for relative descriptions and do not imply any overall orientation of the article in which the described element is located.

As used in this specification and the appended claims, the singular forms “a”, “an”, and “the” encompass embodiments having plural referents, unless the content clearly dictates otherwise.

As used in this specification and the appended claims, the term “or” is generally employed in its sense including “and/or” unless the content clearly dictates otherwise. The term “and/or” means one or all of the listed elements or a combination of any two or more of the listed elements.

As used herein, “have”, “having”, “include”, “including”, “comprise”, “comprising” or the like are used in their open ended sense, and generally mean “including, but not limited to”. It will be understood that “consisting essentially of”, “consisting of”, and the like are subsumed in “comprising” and the like. For example, a conductive trace that “comprises” silver may be a conductive trace that “consists of” silver or that “consists essentially of” silver.

As used herein, “consisting essentially of,” as it relates to a composition, apparatus, system, method or the like, means that the components of the composition, apparatus, system, method or the like are limited to the enumerated components and any other components that do not materially affect the basic and novel characteristic(s) of the composition, apparatus, system, method or the like.

The words “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure, including the claims.

Also herein, the recitations of numerical ranges by endpoints include all numbers subsumed within that range (e.g., 1 to 5 includes 1, 1.5, 2, 2.75, 3, 3.80, 4, 5, etc. or 10 or less includes 10, 9.4, 7.6, 5, 4.3, 2.9, 1.62, 0.3, etc.). Where a range of values is “up to” a particular value, that value is included within the range.

Use of “first,” “second,” etc. in the description above and the claims that follow is not intended to necessarily indicate that the enumerated number of objects is present. For example, a “second” substrate is merely intended to differentiate from another infusion device (such as a “first” substrate). Use of “first,” “second,” etc. in the description above and the claims that follow is also not necessarily intended to indicate that one comes earlier in time than the other.

Thus, embodiments of systems and methods utilizing tong wavelength electromagnetic radiation for feature definition are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation.

1. A method comprising:
directing an incident beam towards a substrate, the substrate having one or more features formed thereon wherein the incident beam has a wavelength from about 10 μm to about 10 mm, and the incident beam interacts with the substrate to form a modulated beam;
varying one or more characteristics of the incident beam while directed towards the substrate;
detecting the modulated beam while varying the one or more characteristics of the incident beam to collect a spectrum; and
determining at least one spatial metric of the at least one feature based on the collected spectrum.

2. The method according to claim 1, wherein the one or more characteristic that is changed is the angle of incidence of the incident beam

3. The method according to claim 1, wherein the one or more characteristic that is changed is the wavelength of the incident beam

4. The method according to claim 1 further comprising gathering a standard spectrum from a standard sample, and normalizing the spectrum based on the standard spectrum in order to determine the at least one spatial metric.

5. The method according to claim 1 further comprising predicting a theoretical spectrum that would be generated from a substrate having desired features, and comparing the collected spectrum to the theoretical spectrum to predict a spatial metric.

6. The method according to claim 1, wherein the spatial metric is a product of: a lithography process, a deposition process, a milling process, an etching process, a polishing process, or a combination thereof.

7. The method according to claim 6 further comprising changing one or more processes being undertaken on the substrate based on the determined spatial metric.

8. A system comprising:
a source of radiation, the radiation having a wavelength from about 10 μm to about 10 mm;
a detector configured to detect radiation having a wavelength from about 10 μm to about 10 mm;
a sample support configured to hold at least one wafer; and
a wafer processing system configured to carry out at least one process on the at least one wafer on the platform.

9. The system according to claim 8, wherein the source of radiation is selected from: Smith-Purcell cells, free electron lasers, and backward wave oscillators (BWO).

10. The system according to claim 8, wherein the detector is selected from: Golay cells, and Bolometers.

11. The system according to claim 8, wherein the source and detector are a solid-state source and a solid-state detector respectively.

12. The system according to claim 8 further comprising at least one polarizer and at least one analyzer.

13. A system comprising:
a source of radiation, the radiation having a wavelength from about 10 μm to about 10 mm;
a detector configured to detect radiation having a wavelength from about 10 μm to about 10 mm;
a sample support configured to hold at least one wafer; and
a process environment configured to carry out one or more processes on the at least one wafer,
wherein the sample support is positioned within a process environment, and the source of radiation and the detector are positioned external to but in communication with the process environment.

14. The system according to claim 13 further comprising a processor configured to obtain information from the detector and determine one or more spatial metric of the wafer based on information from the detector.

15. The system according to claim 14 further comprising a controller in communication with the processor, wherein the controller controls the one or more process on the at least one or more wafer.

16. The system according to claim 15, wherein the controller can modify the process based on information from the processor.

17. The system according to claim 13, wherein the process environment is configured to carry out lithography processes, deposition processes, milling processes, etching processes, polishing processes, or some combination thereof.

18. The system according to claim 13, wherein the source of radiation is selected from: Smith-Purcell cells, free electron lasers, and backward wave oscillators (BWO); and the detector is selected from: Golay cells, and Bolometers.

19. The system according to claim 13, wherein the source and detector are a solid-state source and a solid-state detector respectively.

20. The system according to claim 13 further comprising at least one polarizer and at least one analyzer.
